(19) United States
(12) Patent Application Publication
(10) Pub. No.: US 2025/0321141 A1
(43) Pub. Date: Oct. 16, 2025

(54) SEMICONDUCTOR MODULE

(71) Applicant: FUJI ELECTRIC CO., LTD., Kawasaki-shi (JP)

(72) Inventor: Motomitsu IWAMOTO, Matsumoto-city (JP)

(73) Assignee: FUJI ELECTRIC CO., LTD., Kawasaki-shi (JP)

(21) Appl. No.: 19/060,401

(22) Filed: Feb. 21, 2025

(30) Foreign Application Priority Data
Apr. 11, 2024 (JP) 2024-064185

(51) Int. Cl. G01K 1/02; H01L 23/34

(52) U.S. Cl. CPC G01K 1/026; H01L 23/34; G01K 2219/00

(57) ABSTRACT

A semiconductor module, including: a first terminal and a second terminal; a driver circuit including a plurality of pairs of switching devices, each pair including a first switching device on a power supply side of the semiconductor module, and a second switching device on a ground side of the semiconductor module; at least one temperature sensor, each configured to detect a temperature of at least one switching device among the plurality of pairs of switching devices; a control circuit configured to control switching of the plurality of pairs of switching devices; and an output circuit configured to output a signal indicative of the temperature via the first and second terminals.

### CROSS-REFERENCE TO RELATED APPLICATION

This application claims priority pursuant to 35 U.S.C. § 119 from Japanese Patent Application No. 2024-064185, filed on Apr. 11, 2024, of which is incorporated herein by reference.

### BACKGROUND

### Technical Field

The present disclosure relates to a semiconductor module.

### Related Art

There are modules including semiconductor chips where switching devices, such as insulated gate bipolar transistors (IGBTs), diodes for temperature detection, and the like are formed (see, for example, Japanese Patent No. 5862434, International Publication No. WO2017/169693, and Japanese Patent Application Publication Nos. 2005-166987 and 2001-133330). Such modules are generally called intelligent power modules (IPMs) for power conversion apparatuses.

Incidentally, a switching device may be broken when a current passes through the device, increased in temperature, and is brought into an overheated state. An increase or a decrease in the temperature of a switching device also affects the lifetime of the switching device. It is therefore preferable to measure the temperature of a switching device.

### SUMMARY

A main aspect of the present disclosure is a semiconductor module that comprises a first terminal and a second terminal; a driver circuit including a plurality of pairs of switching devices, each pair including: a first switching device on a power supply side of the semiconductor module, and a second switching device on a ground side of the semiconductor module; at least one temperature sensor, each configured to detect a temperature of at least one switching device among the plurality of pairs of switching devices; a control circuit configured to control switching of the plurality of pairs of switching devices; and an output circuit configured to output a signal indicative of the temperature via the first and second terminals.

### BRIEF DESCRIPTION OF THE DRAWINGS

FIG. 1 is a diagram showing an example overall configuration of a power module 1.

FIG. 2 is a diagram showing an example configuration of a temperature detection circuit 9.

FIG. 3 is a diagram showing an example operation by the temperature detection circuit 9.

FIG. 4 is a diagram showing an example configuration of a driver circuit 10.

FIG. 5 is a diagram showing an example configuration of a temperature detection circuit 12.

FIG. 6 is a diagram showing an example operation by the temperature detection circuit 12.

FIG. 7 is a diagram showing an example overall configuration of a power module 1a.

FIG. 8 is a diagram showing an example configuration of part of a power module 13.

### DETAILED DESCRIPTION

At least the following matters will be revealed by what is described herein and the drawings attached hereto. A preferred embodiment of the present disclosure is described below with reference to the drawings. The same or like constituents, members, and the like shown in the drawings are denoted by the same reference numerals, and repetitive descriptions are omitted as needed.

### EMBODIMENTS

### <<Overall Configuration of the Power Module 1>>>

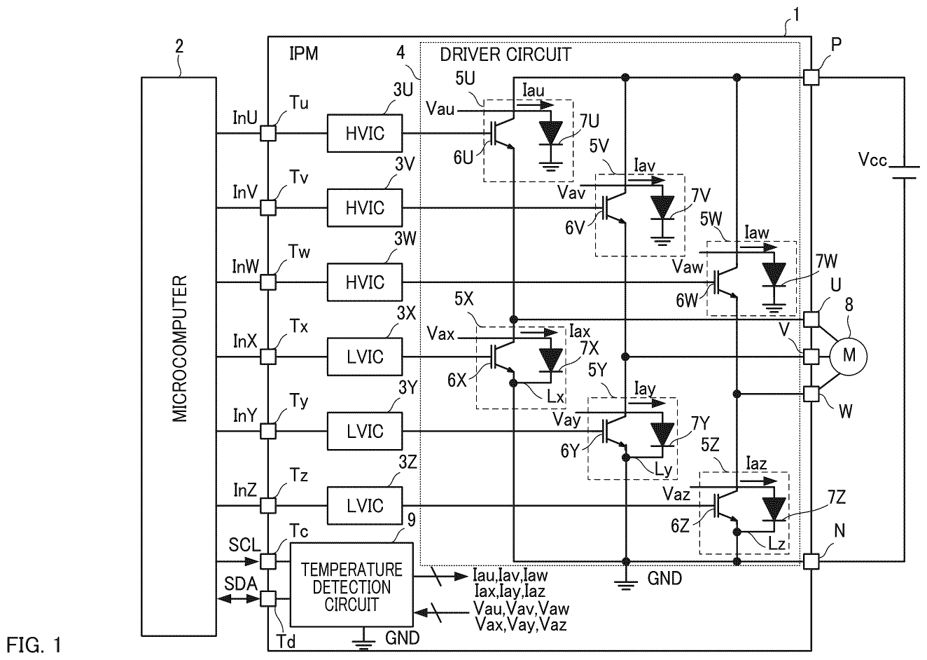

FIG. 1 is a block diagram showing an overall configuration of a power module 1 of an embodiment of the present disclosure.

The power module 1 of an embodiment of the present disclosure is a semiconductor module that drives a three-phase motor 8, a load, as instructed by a microcomputer 2, i.e., the power module 1 is an IPM. The power module 1 is configured including HVICs 3U, 3V, and 3W, LVICs 3X, 3Y, and 3Z, a driver circuit 4, a temperature detection circuit 9, and terminals Tu, Tv, Tw, Tx, Ty, Tz, Tc, Td, P, N, U, V, and W.

The driver circuit 4 is controlled by the HVICs 3U, 3V, and 3W and the LVICs 3X, 3Y, and 3Z, and the driver circuit 4 drives the three-phase motor 8. Further, as will be described in detail later, the HVICs 3U, 3V, and 3W and the LVICs 3X, 3Y, and 3Z control the driver circuit 4 according to drive signals InU, InV, InW, InX, InY, and InZ inputted thereto via the terminals Tu, Tv, Tw, Tx, Ty, and Tz, respectively. The driver circuit 4 is configured including semiconductor chips 5U, 5V, 5W, 5X, 5Y, and 5Z.

The semiconductor chip 5U includes a U-phase switching device 6U, which is an element on the power supply voltage Vcc side (i.e., the power supply side), and a diode 7U for detecting the temperature of the switching device 6U. The switching device 6U applies the power supply voltage Vcc, which is applied to the terminal P, to the three-phase motor 8 via the terminal U.

Similarly, the semiconductor chips 5V, 5W, 5X, 5Y, and 5Z respectively include switching devices 6V, 6W, 6X, 6Y, and 6Z of the corresponding phases (V-phase, W-phase, X-phase, Y-phase, and W-phase) and diodes 7V, 7W, 7X, 7Y, and 7Z for temperature detection. Further, using a diode to detect the temperature of a switching device is capable of accurately detecting the temperature of the switching device.

The diodes 7U, 7V, 7W, 7X, 7Y, and 7Z correspond to the “temperature sensor.” Further, the switching devices 6U, 6V, 6W, 6X, 6Y, and 6Z are hereinafter written as the “switching devices 6U to 6Z.” Similarly, the diodes 7U, 7V, 7W, 7X, 7Y, and 7Z are hereinafter written as the “diodes 7U to 7Z.”

Moreover, the switching devices 6V and 6W apply the power supply voltage Vcc to the three-phase motor 8 via the terminals V and W, respectively, and the switching devices 6X, 6Y, and 6Z apply a ground voltage to the three-phase motor 8 via the terminals U, V, and W, respectively. The switching devices 6V and 6W are elements on the power supply voltage Vcc side (i.e., the power supply side), and the switching devices 6X, 6Y, and 6Z are elements on the ground side to which the ground voltage is applied from the terminal N. The switching devices 6U, 6V, and 6W correspond to the “first switching device,” and the switching devices 6X, 6Y, and 6Z correspond to the “second switching device.”

IGBTs are used as the switching devices 6U, 6V, 6W, 6X, 6Y, and 6Z in an embodiment of the present disclosure.

However, they are not limited to IGBTs, and may be, for example, bipolar transistors or MOS transistors.

In addition, when the switching devices 6U to 6Z are IGBTs, the switching device 6U and the diode 7U are electrically separated from each other. Similarly, the switching device 6V and the diode 7V are electrically separated from each other, and the switching device 6W and the diode 7W are electrically separated from each other, as well. “To be electrically separated from each other” means, in a case of the switching device 6U and the diode 7U, for example, the emitter of the switching device 6U and the cathode of the diode 7U are not coupled to each other by wiring or the like in the semiconductor chip 5U. The cathodes of the diodes 7U to 7Z are coupled to the ground.

Meanwhile, the emitter of the switching device 6X and the cathode of the diode 7X are coupled by wiring Lx, the emitter of the switching device 6Y and the cathode of the diode 7Y are coupled by wiring Ly, and the emitter of the switching device 6Z and the cathode of the diode 7Z are coupled by wiring Lz. The wiring Lx, Ly, and Lz are coupled to the ground. Accordingly, the cathodes of the diodes 7U to 7Z are coupled to the ground. For example, the emitter of the switching device 6X corresponds to the “ground-side electrode of the second switching device,” and the cathode of the diode 7X corresponds to the “ground-side electrode of the temperature sensor.”

The HVICs 3U, 3V, and 3W are integrated circuits (ICs) for controlling switching of the switching devices 6U, 6V, and 6W, which are on the upper arm side of the bridge circuit, according to the drive signals InU, InV, and InW inputted thereto from the microcomputer 2.

The LVICs 3X, 3Y, and 3Z are integrated circuits (ICs) for controlling the switching of the switching devices 6X, 6Y, and 6Z, which are on the lower arm side of the bridge circuit, according to the drive signals InX, InY, and InZ inputted thereto from the microcomputer 2. The HVIC 3U and the LVIC 3X, the HVIC 3V and the LVIC 3Y, or the HVIC 3W and the LVIC 3Z correspond to the “control circuit.”

The temperature detection circuit 9 detects the temperatures of the switching devices 6U to 6Z and outputs signals indicative of temperature to the microcomputer 2. Specifically, the temperature detection circuit 9 supplies currents Iau, Iav, Iaw, Iax, Iay, and Iaz (hereinafter written as “Iau to Iaz”) to the diodes 7U to 7Z, respectively.

Moreover, the temperature detection circuit 9 detects forward voltages Vau, Vav, Vaw, Vax, Vay, and Vaz (hereinafter written as “Vau to Vaz”) at the diodes 7U to 7Z, as voltages indicative of temperature. Then, based on the detected voltages, the temperature detection circuit 9 outputs digital signals indicative of temperature to the microcomputer 2 via the terminals Tc and Td. The forward voltages Vau to Vaz at the diodes 7U to 7Z have negative temperature characteristics. In a case of the diode 7U, for example, the forward voltage Vau is a voltage applied to the diode 7U in a direction from the anode to the cathode when the current Iau flows through the diode 7U. The same is true for the diodes 7V to 7Z.

### ==Configuration of the Temperature Detection Circuit 9==

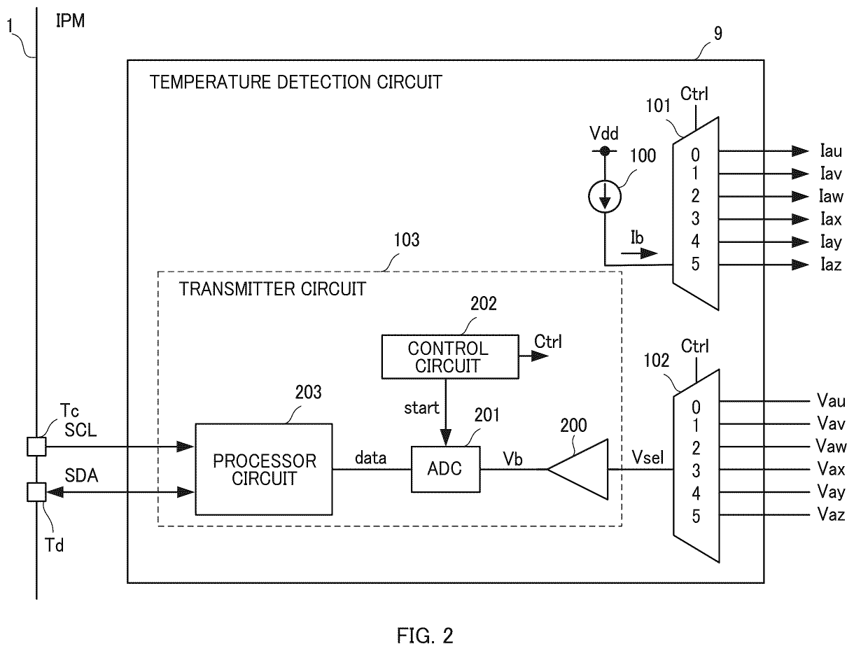

FIG. 2 is a diagram showing an example configuration of the temperature detection circuit 9. The temperature detection circuit 9 is configured including a current source 100, multiplexers 101 and 102, and a transmitter circuit 103.

The current source 100 generates a predetermined current Ib. The multiplexer 101 selects one of the diodes 7U to 7Z according to a signal Ctrl and supplies the selected diode with the predetermined current Ib as corresponding one of currents Iau to Iaz. Specifically, when the signal Ctrl indicates “0,” the multiplexer 101 supplies the diode 7U with the predetermined current Ib as the current Iau.

Similarly, when the signal Ctrl indicates “1,” “2,”, “3,”, “4,” or “5,” the multiplexer 101 supplies the predetermined current Ib as corresponding one of the currents Iav to Iaz. The currents Iav to Iaz are supplied to the diodes 7V to 7Z, respectively. The multiplexer 101 corresponds to the “second selection circuit.”

According to the signal Ctrl, the multiplexer 102 outputs one of the forward voltages Vau to Vaz at the diodes 7U to 7Z as a voltage Vsel. Specifically, when the signal Ctrl indicates “0,” the multiplexer 102 outputs the forward voltage Vau as the voltage Vsel. Similarly, when the signal Ctrl indicates “1,” “2,”, “3,”, “4,” or “5,” the multiplexer 102 selects corresponding one of the forward voltages Vav to Vaz and outputs it as the voltage Vsel. The multiplexer 102 corresponds to the “first selection circuit.”

Based on the voltage Vsel, the transmitter circuit 103 transmits a signal indicative of temperature. Specifically, the transmitter circuit 103 amplifies the voltage Vsel, converts it to digital value data “data,” processes the data “data,” and outputs it as a signal indicative of temperature to the microcomputer 2 via the terminals Tc and Td. The transmitter circuit 103 is configured including an amplification circuit 200, an analog-to-digital conversion (ADC) circuit 201, a control circuit 202, and a processor circuit 203.

The amplification circuit 200 amplifies the voltage Vsel and outputs it as a voltage Vb. Based on a signal “start” from the control circuit 202, the analog-to-digital conversion circuit 201 converts the voltage Vb into the digital value “data”. The analog-to-digital conversion circuit 201 converts the voltage Vb into a digital value at a frequency of, for example, twice or more of the switching frequency of the switching devices 6U and 6X.

Further, the control circuit 202 changes the signal Ctrl from “0” to “5” stepwise at predetermined time intervals. The processor circuit 203 processes the digital value “data” from the analog-to-digital conversion circuit 201 and outputs the result via the terminals Tc and Td.

Although an embodiment of the present disclosure shows an example where the temperature detection circuit 9 configures an I2C interface that outputs a signal SDA via the terminal Td based on a clock signal SCL at the terminal Tc, the temperature detection circuit 9 is not limited to this as long as the interface is configured by a small number of terminals. The terminal Tc corresponds to the “first terminal,” the terminal Td corresponds to the “second terminal,” and the temperature detection circuit 9 corresponds to the “output circuit”.

Moreover, in an embodiment of the present disclosure, based on the digital value “data,” the processor circuit 203 sequentially outputs signals indicating, for example, the temperatures of the switching devices 6U to 6Z. Based on the digital value “data,” the processor circuit 203 may output a signal indicating, for example, the average value of the temperatures of the switching devices 6U to 6Z. Further, based on the digital value “data,” the processor circuit 203 may output a signal indicating, for example, the maximum value of the temperatures of the switching devices 6U to 6Z.

### ==Operation by the Temperature Detection Circuit 9==

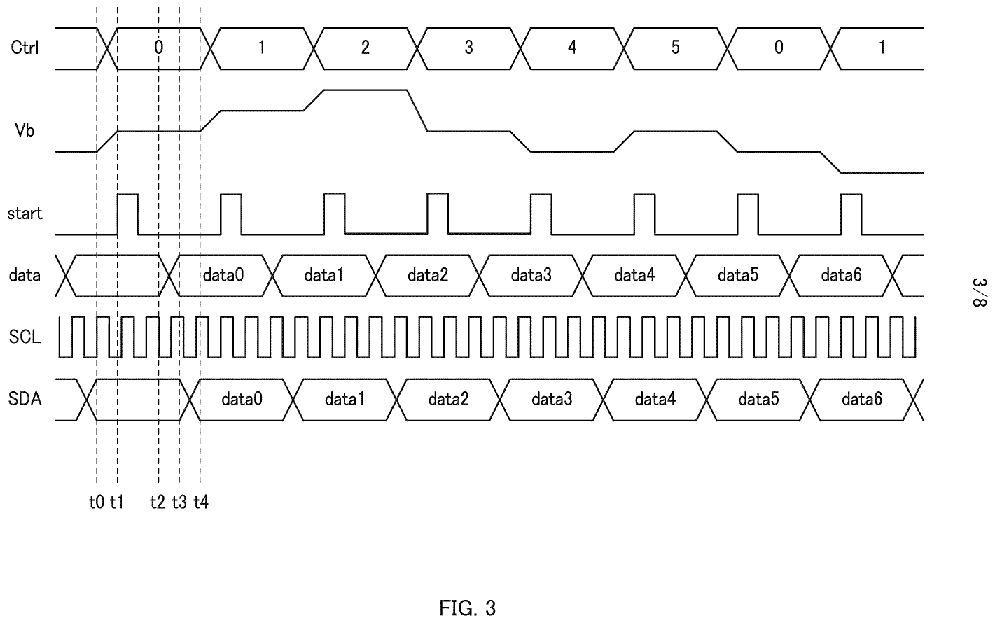

FIG. 3 is a diagram showing an example operation by the temperature detection circuit 9. The temporal relations between the clock signal SCL and the signal SDA in FIG. 3 are conceptually shown.

At time point to, once the control circuit 202 outputs the signal Ctrl indicative of “0,” the multiplexer 101 passes the current Ib from the current source 100 through the diode 7U as the current Iau in order to measure the temperature of the switching device 6U. As a result of the current Iau passing through the diode 7U, the forward voltage Vau is generated at the diode 7U, and the multiplexer 102 outputs the voltage Vau to the transmitter circuit 103 as the voltage Vsel because the control circuit 202 is outputting the signal Ctrl indicative of “0.” The amplification circuit 200 amplifies the voltage Vsel and outputs it as the voltage Vb.

At time point t1 when the voltage Vb stabilizes, the control circuit 202 outputs the signal “start” to the analog-to-digital conversion circuit 201 to convert the voltage Vb into the digital value “data.” The analog-to-digital conversion circuit 201 starts a conversion operation.

At time point t2 when the analog-to-digital conversion circuit 201 completes the conversion, the analog-to-digital conversion circuit 201 outputs a digital value “data0” as the digital value “data.” The processor circuit 203 starts processing the digital value “data0.”

At time point t3 when the processor circuit 203 completes the processing of the digital value “data0,” the processor circuit 203 outputs the digital value “data0” as the signal SDA via the terminal Td based on the clock signal SCL at the terminal Tc.

After time point t4, the switching device to measure the temperature thereof is sequentially changed to the switching devices 6V to 6Z, and a similar operation is repeated. As such, since a signal indicative of temperature is outputted via the terminals Tc and Td, the number of terminals needed for the power module 1 can be reduced.

In the example described in an embodiment of the present disclosure, for example, based on the digital value “data,” the processor circuit 203 sequentially outputs signals indicating the temperatures of the switching devices 6U to 6Z. However, the processor circuit 203 may perform other processing (such as averaging or detection of the maximum value) and output a signal, obtained by processing the digital value “data” (a signal indicating, e.g., the average value or the maximum value), as the signal SDA via the terminal Td based on the clock signal SCL at the terminal Tc. Further, the order of the switching devices to measure the temperature thereof is not limited to the order shown in an embodiment of the present disclosure.

### MODIFICATION EXAMPLES

==Configuration of the Driver circuit 10==

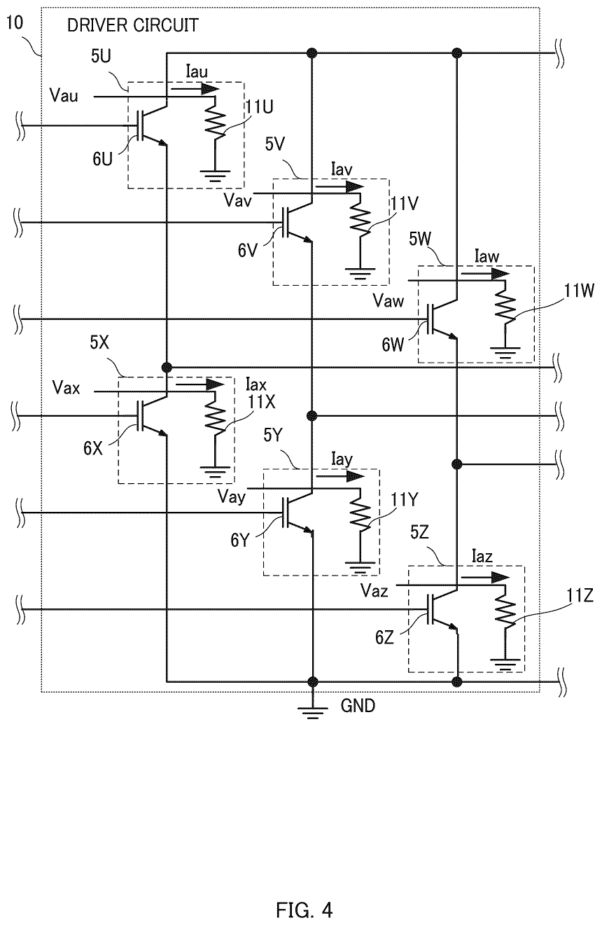

FIG. 4 is a diagram showing an example configuration of a driver circuit 10 according to a modification. The driver circuit 10 uses resistors made of polysilicon as elements for measuring the temperatures of the switching devices.

Specifically, the semiconductor chip 5U is formed of the switching device 6U and a resistor 11U. The same is true for the semiconductor chips 5V to 5Z. Also, the resistors 11U, 11V, 11W, 11X, 11Y, and 11Z are made of polysilicon.

The switching device 6U and the resistor 110 are electrically separated from each other. The same is true for the switching device 6V and the resistor 11V and for the switching device 6W and the resistor 11W. In addition, for example, the voltage Vau generated at the resistor 11U when the current Iau is passed through the resistor 110 has positive temperature characteristics.

Further, for example, temperature detection accuracy is lower when using the resistor 11U than using the diode 7U. However, for example, the electrical separation can be achieved with a thinner oxidization film when the switching device 6U and the resistor 11U are manufactured on the semiconductor chip 5U than when the diode 7U is manufactured along with the switching device 6U. This facilitates manufacturing of the semiconductor chip 5U. The expression “electrically separated from each other” herein means, in a case of the switching device 6U and the resistor 11U, for example, the emitter of the switching device 6U and the resistor 11U are not coupled to each other with wiring or the like in the semiconductor chip 5U.

### ==Configuration of the Temperature Detection Circuit 12==

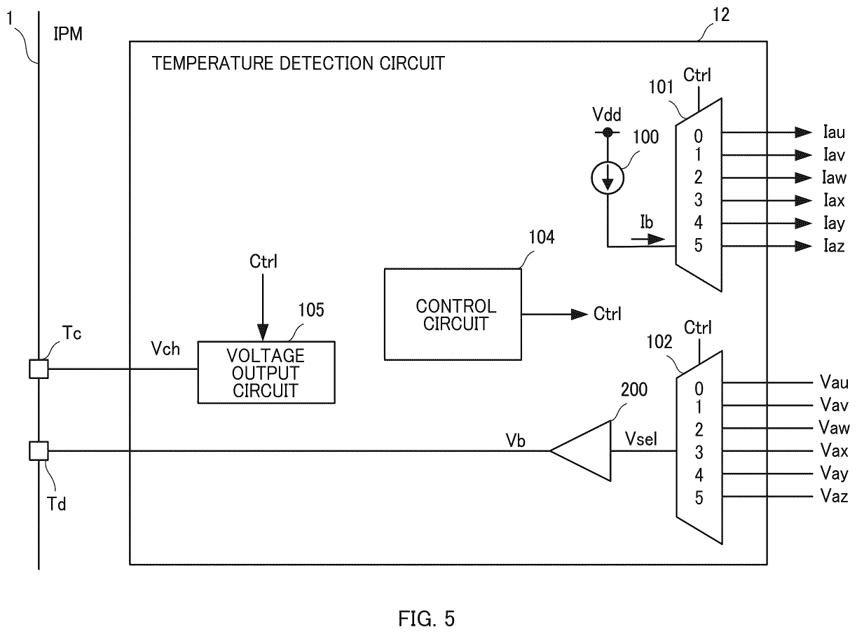

FIG. 5 is a diagram showing an example configuration of a temperature detection circuit 12. An embodiment of the present disclosure shows an example where the temperature detection circuit 9 configures an I2C interface that outputs the signal SDA via the terminal Td based on the clock signal SCL at the terminal Tc. Alternatively, an analog signal may be outputted, with the same number of terminals.

For example, the temperature detection circuit 12 outputs the forward voltage Vau at the diode 7U as an analog value. Specifically, the temperature detection circuit 12 supplies the diodes 7U, 7V, 7W, 7X, 7Y, and 7Z with the currents Iau to Iaz, respectively.

Further, the temperature detection circuit 12 detects the forward voltages Vau to Vaz at the diodes 7U to 7Z as voltages indicative 4 temperature. The temperature detection circuit 12 then outputs the detected voltage to the microcomputer 2 via the terminal Td as an analog signal indicative of temperature. The temperature detection circuit 12 then outputs an analog voltage Vch via the terminal Tc, the analog voltage Vch indicating whether an analog signal indicative of the temperature of any of the switching devices 6U to 6Z is being outputted via the terminal Td.

The temperature detection circuit 12 is configured including the current source 100, the multiplexers 101 and 102, the amplification circuit 200, a control circuit 104, and a voltage output circuit 105. The control circuit 104 changes the signal Ctrl sequentially from “0” to “5” at predetermined time intervals and outputs the signal Ctrl. The amplification circuit 200 outputs the voltage Vb to the microcomputer 2 via the terminal Td.

According to the signal Ctrl, the voltage output circuit 105 outputs, via the terminal Tc, the analog voltage Vch indicating whether an analog signal indicative of the temperature of any of the switching devices 6U to 6Z is being outputted via the terminal Td. This makes signals indicative of the temperatures of the switching devices 6U to 6Z possible to be outputted even with a small number of terminals.

### ==Operation by the Temperature Detection Circuit 12==

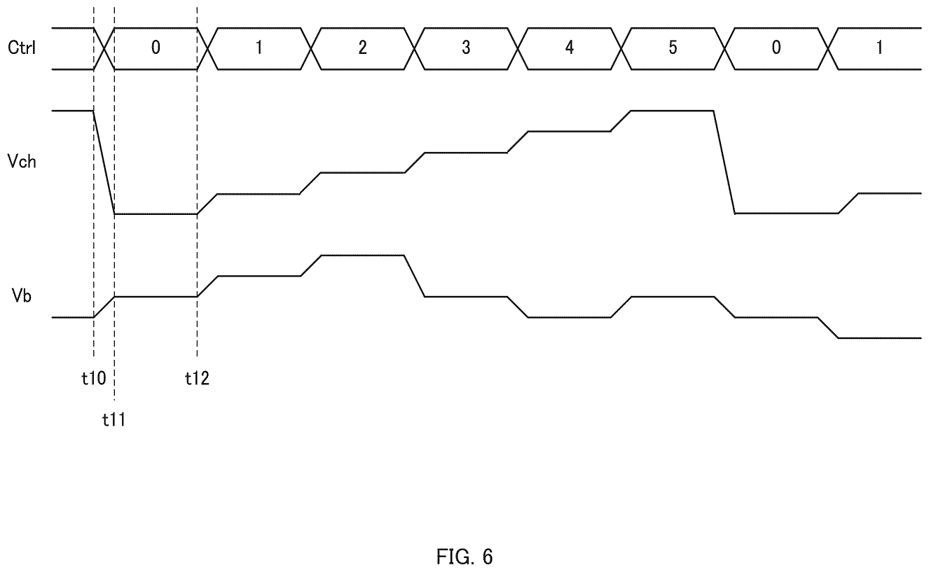

FIG. 6 is a diagram showing an example operation by the temperature detection circuit 12. At time point t10, once the control circuit 104 outputs the signal Ctrl indicative of “0,” the multiplexer 101 supplies the current Ib from the current source 100 to the diode 7U as the current Iau in order to measure the temperature of the switching device 6U.

Then, as a result of the current Iau passing through the diode 7U, the forward voltage Vau is generated at the diode 7U, and the multiplexer 102 outputs the voltage Vau to the amplification circuit 200 as the voltage Vsel because the control circuit 104 is outputting the signal Ctrl indicative of “0.” The amplification circuit 200 amplifies the voltage Vsel and outputs it as the voltage Vb via the terminal Td. The voltage output circuit 105 outputs the voltage Vch indicating that the analog signal Vb indicative of the temperature of the switching device 6U is outputted.

At time point t11, the voltage Vch and the analog signal Vb stabilize. Thus, after time point t11, the microcomputer 2 can detect the temperature of the switching device 6U by detecting the voltage Vch and the analog signal Vb. A similar operation is repeated after time point t12. Thus, even if analog voltages are outputted to the terminals Tc and Td, the temperatures of the switching devices 6U to 6Z can be outputted from the temperature detection circuit 12 to the microcomputer 2.

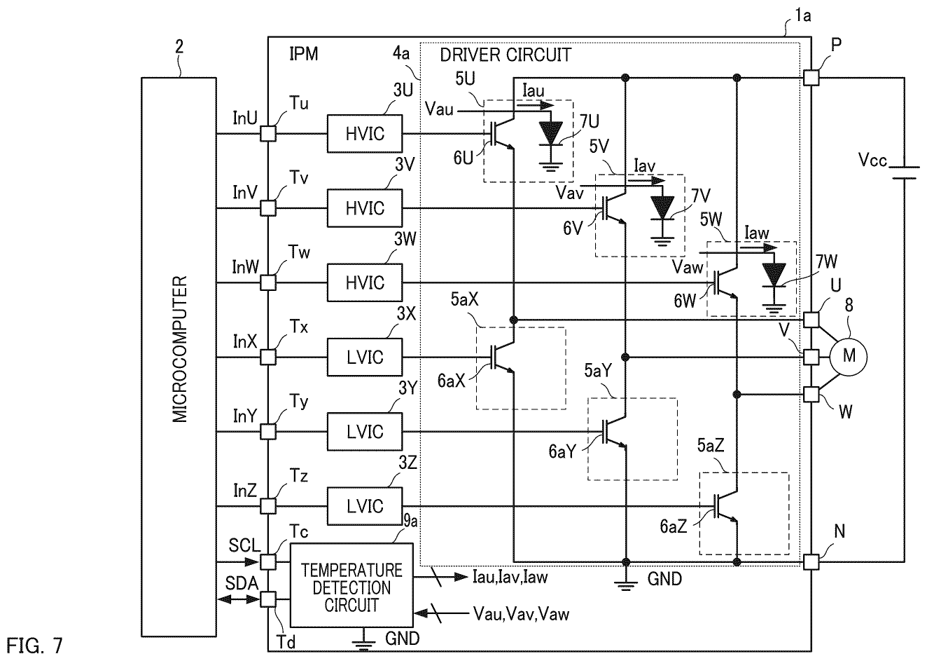

FIG. 7 is a diagram showing an example overall configuration of a power module 1a. The power module 1a is configured including the HVICs 3U, 3V, and 3W, the LVICs 3X, 3Y, and 3Z, a driver circuit 4a, a temperature detection circuit 9a, and the terminals Tu, Tv, Tw, Tx, Ty, Tz, Tc, Td, P, N, U, V, and W.

The driver circuit 4a drives the three-phase motor 8 as controlled by the HVICs 3U, 3V, and 3W and the LVICs 3X, 3Y, and 3Z. The driver circuit 4a is configured including semiconductor chips 5U, 5V, 5W, 5aX, 5aY, and 5aZ.

Unlike those in the driver circuit 4, semiconductor chips 5aX, 5aY, 5aZ do not include the diodes 7X, 7Y, and 7Z for temperature detection.

The temperature detection circuit 9a detects the temperatures of the switching devices 6U to 6W and outputs signals indicative of temperature to the microcomputer 2. Specifically, the temperature detection circuit 9a supplies the diodes 7U, 7V, and 7W with the currents Iau, Iav, and Iaw, respectively.

Further, the temperature detection circuit 9a detects the forward voltages Vau, Vav, and Vaw at the diodes 7U to 7W as voltages indicative of temperature. In this way, even if not all semiconductor chips include an element for temperature detection and temperature is detected of only some of the switching devices, breakage and lifetime of the switching devices can be detected. Although the semiconductor chips 5U, 5V, and 5W include diodes for temperature detection in FIG. 7, only the semiconductor chip 5U may include a diode for temperature detection, for example.

### COMPARATIVE EXAMPLE

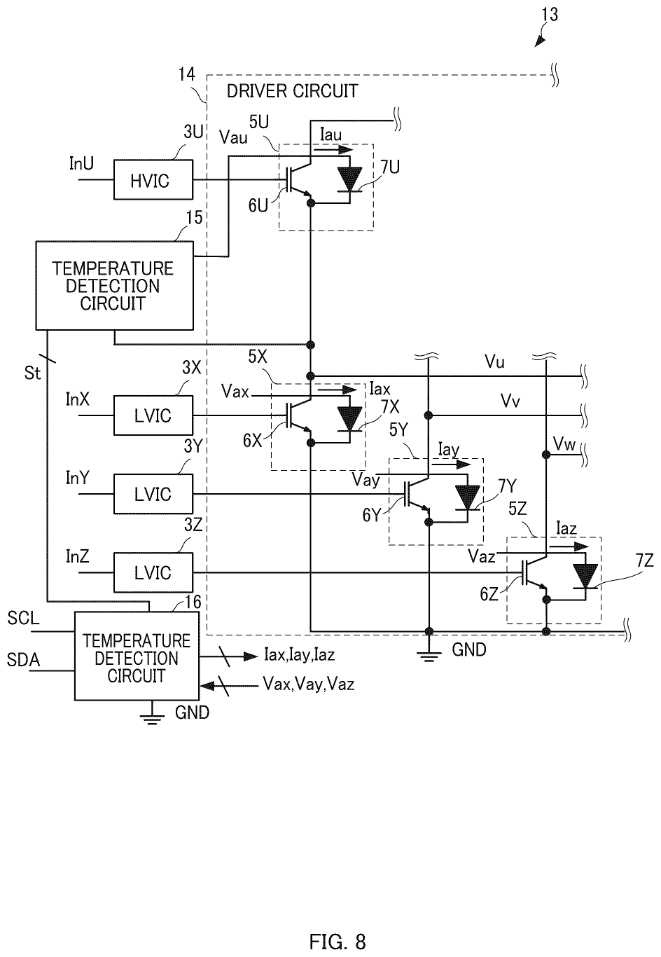

FIG. 8 is a diagram showing an example configuration of part of a power module 13 as a comparative example. The power module 13 is configured including the HVICs 3U, 3V, and 3W, the LVICs 3X, 3Y, and 3Z, a driver circuit 14, temperature detection circuits 15 and 16, and the terminals Tu, Tv, Tw, Tx, Ty, Tz, Tc, Td, P, N, U, V, and W.

In the driver circuit 14, the emitter of the switching device 6U and the cathode of the diode 7U are coupled to each other. The same is true for the switching device 6V and the diode 7V and for the switching device 6W and the diode 7W.

The temperature detection circuit 15 needs to detect the forward voltage Vau at the diode 7U in order to measure the temperature of the switching device 6U. To this end, the temperature detection circuit 15 needs to use a voltage Vu applied to the terminal U as a reference voltage and therefore needs to be provided separately from the that detects the temperature detection circuit 15 temperatures of the switching devices 6X, 6Y, and 6Z.

The same is true for the switching devices 6V and 6W; thus, a total of three temperature detection circuits are needed to detect the temperatures of the switching devices 6U, 6V, and 6W, and furthermore, a single temperature detection circuit is needed to detect the temperatures of the switching devices 6X, 6Y, and 6Z. The temperature detection circuit 16 receives a signal St from the temperature detection circuits that detect the temperatures of the switching devices 6U, 6V, and 6W and outputs signals indicative of temperature via the terminals Tc and Td.

For example, in a case of the comparative example where the emitter of the switching device 6U and the cathode of the diode 7U are coupled to each other, many temperature detection circuits are needed in order to measure the temperatures of the respective switching devices. By contrast, when the emitter of the switching device 6U and the cathode of the diode 7U are electrically separated from each other like in an embodiment of the present disclosure, for example, the temperatures of the switching devices 6U to 6Z can be measured with only the temperature detection circuit 9.

=====Overview=====

The power module 1 has been described above as an embodiment of the present disclosure. The power module 1 has the terminals Tc and Td, the driver circuit 4, the diodes 7U to 7Z, the HVICs 3U, 3V, and 3W, the LVICs 3X, 3Y, and 3Z, and the temperature detection circuit 9. This makes it possible to provide a semiconductor module that can output a signal indicative of temperature to the outside.

The temperature detection circuit 9 outputs the signal SDA via the terminal Td based on the clock signal SCL at the terminal Tc. This allows the signal SDA, which is a digital signal, to be less affected by noise from other circuits in the power module 1 (such as the HVIC 3U, the LVIC 3X, and the driver circuit 4).

Further, the temperature detection circuit 9 includes the multiplexer 102 and the transmitter circuit 103. This makes it possible to measure the temperatures of the switching devices 6U to 6Z and also to reduce the circuit scale of the temperature detection circuit 9.

Furthermore, the temperature detection circuit 9 includes the current source 100 and the multiplexer 101. This makes it possible to supply currents to the diodes 7U to 7Z with only the current source 100 and also to reduce the circuit scale of the temperature detection circuit 9.

The transmitter circuit 103 has the amplification circuit 200, the analog-to-digital conversion circuit 201, and the processor circuit 203, and the analog-to-digital conversion circuit 201 converts the voltage Vb into a digital value at a frequency of, for example, twice or more of the switching frequency of the switching devices 6U and 6X. This makes it possible to measure the temperatures of the switching devices 6U to 6Z accurately according to the switching frequencies of the switching devices 6U to 6Z.

The switching and the diode 7U are electrically separated from each other. This is true for the switching device 6V and the diode 7V and for the switching device 6V and the diode 7V. This makes it possible to measure the temperatures of the switching devices 6U to 6Z with only the temperature detection circuit 9.

Moreover, the power module 1 includes the wiring Lx, Ly, and Lz. Thus, the same semiconductor chips as the semiconductor chips 5U, 5V, and 5W can be used as the semiconductor chips 5X, 5Y, and 5Z, which can reduce the cost for manufacturing the power module 1.

Further, for example, using the diode 7U as a temperature sensor to measure the temperature of the switching device 6U is capable of accurately measuring temperature.

In addition, for example, using the resistor 11U as a temperature sensor to measure the temperature of the switching device 6U makes it possible to reduce the thickness of the oxidized film for electrically separating the switching device 6U and the resistor 11U from each other.

The present disclosure is directed to provision of a semiconductor module that can output a signal indicative of temperature to the outside.

The present disclosure can provide a semiconductor module that can output a signal indicative of temperature to the outside.

The above embodiment has been provided to facilitate the understanding of the present invention and is not to be interpreted as limiting the present invention. Further, it goes without saying that the present invention may be modified or altered without departing from the gist thereof and equivalents thereof are encompassed by the present invention.

What is claimed is:

1. A semiconductor module comprising:
a first terminal and a second terminal;
a driver circuit including a plurality of pairs of switching devices, each pair including:
a first switching device on a power supply side of the semiconductor module, and
a second switching device on a ground side of the semiconductor module;
at least one temperature sensor, each configured to detect a temperature of at least one switching device among the plurality of pairs of switching devices;
a control circuit configured to control switching of the plurality of pairs of switching devices; and
an output circuit configured to output a signal indicative of the temperature via the first and second terminals.

2. The semiconductor module according to claim 1, wherein the output circuit outputs the signal via the second terminal based on a clock signal at the first terminal.

3. The semiconductor module according to claim 2, wherein
the at least one temperature sensor is a plurality of temperature sensors, and
the output circuit includes
a first selection circuit configured to sequentially select outputs from the plurality of temperature sensors, and
a transmitter circuit configured to transmit the signal based on a selection result of the first selection circuit.

4. The semiconductor module according to claim 3, wherein
the output circuit further includes
a current source configured to generate a predetermined current, and
a second selection circuit configured to sequentially select the plurality of temperature sensors such that the predetermined current is supplied to each of the plurality of temperature sensors.

5. The semiconductor module according to claim 4, wherein
the transmitter circuit has
an amplification circuit configured to amplify the selection result of the first selection circuit,
an analog-to-digital conversion circuit configured to convert an output from the amplification circuit into a digital value, at a frequency that is twice or more of a switching frequency of the first and second switching devices, and
a processor circuit configured to process the signal based on an output from the analog-to-digital conversion circuit.

6. The semiconductor module according to claim 1, wherein each of the first switching devices and one of the at least one temperature sensor configured to detect the temperature of said each first switching device are electrically separated from each other.

7. The semiconductor module according to claim 6, wherein
each of the second switching devices and the at least one temperature sensor has a ground-side electrode, and
each of the second switching devices, and one of the at least one temperature sensor configured to detect the temperature of said each second switching device, have wiring coupling ground-side electrodes thereof.

8. The semiconductor module according to claim 7, wherein the at least one temperature sensor is each a diode.

9. The semiconductor module according to claim 7, wherein the at least one temperature sensor is each a resistor made of polysilicon.
